(19) United States
(12) Patent Application Publication
(10) Pub. No.: US 2025/0259821 A1
(43) Pub. Date: Aug. 14, 2025

(54) METHOD TO ENHANCE ETCH RATE AND IMPROVE CRITICAL DIMENSION OF FEATURES AND MASK SELECTIVITY

(71) Applicant: Lam Research Corporation, Fremont, CA (US)

(72) Inventors: Juline SHOEB, Fremont, CA (US); Myeong Yeol CHOI, Campbell, CA (US); Alexander Miller PATERSON, San Jose, CA (US)

(73) Assignee: Lam Research Corporation, Fremont, CA (US)

(21) Appl. No.: 18/858,002

(22) PCT Filed: Apr. 6, 2023
(86) PCT No.: PCT/US2023/017797

§ 371 Date: Oct. 18, 2024

Related U.S. Application Data
(60) Provisional application No. 63/363,558, filed on Apr. 25, 2022.

(51) Int. Cl. H01J 37/32; H01L 21/3065

(52) U.S. Cl. CPC H01J 37/32128; H01L 21/3065; H01J 2237/334

(57) ABSTRACT

A method of generating a voltage pulse includes generating a first non-sinusoidal continuous wave voltage (NSCWV) waveform for a first time duration of a clock cycle. The first NSCWV signal comprises a first base voltage and a first frequency. The method further includes performing a first transition to change from the first NSCWV signal to a second NSCWV signal. The second NSCWV signal is generated for a second time duration of the clock cycle. The second NSCWV signal comprises a second base voltage and a second frequency. The method further includes performing a second transition to change from the second NSCWV signal back to the first NSCWV signal. The first transition and the second transition are repeated over the clock cycle.

### CLAIM FOR PRIORITY

This application is a continuation of, and claims the benefit of priority to U.S. Patent Application No. 63/363,558, filed on Apr. 25, 2022, titled “METHOD TO ENHANCE ETCH RATE AND IMPROVE CRITICAL DIMENSION OF FEATURES AND MASK SELECTIVITY,” and which is incorporated by reference in its entirety.

### BACKGROUND

Etch and deposition processes are indispensable components of modern-day semiconductor processing. While a variety of plasma processing techniques may be utilized, inductively coupled plasmas provide advantageous features such as ways to control ion energy and ion angular spread. Controlling ion energy and ion angular spread can provide a plethora of advantages for etch and deposition processes based on inductively coupled plasmas. Ion behavior can be controlled by changing parameters that affect bulk plasma properties and by changing electrical parameters (such as bias voltage) on an electrostatic chuck. Among these two control knobs, methods to change electrical parameters on an electrostatic chuck are being constantly developed to solve a variety of problems in semiconductor device fabrication.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1 illustrates a schematic of an apparatus including an electrostatic chuck coupled with a non-sinusoidal continuous wave voltage source, in accordance with at least one embodiment embodiment of the present disclosure.

FIG. 2 illustrates a relationship between the temperature of ions, electric field, and an angular spread in a sheath region of a plasma, in accordance with at least one embodiment of the present disclosure.

FIG. 3 illustrates a plot of a voltage generated by a non-sinusoidal continuous wave voltage (NSCWV) source, where the voltage level varies between a first level and a second level, in accordance with at least one embodiment of the present disclosure.

FIG. 4 illustrates a plot of a first portion of a voltage generated by the non-sinusoidal continuous wave voltage source in FIG. 3, in accordance with at least one embodiment of the present disclosure.

FIG. 5 illustrates a plot of a second portion of a voltage generated by the non-sinusoidal continuous wave voltage source in FIG. 3, in accordance with at least one embodiment of the present disclosure.

FIG. 6 illustrates a plot of a portion of an applied voltage generated by the non-sinusoidal continuous wave voltage source in FIG. 3, superimposed with a plot of a resultant induced voltage on a surface of a substrate, in accordance with at least one embodiment of the present disclosure.

FIG. 7 illustrates a flow diagram of a method of increasing ion energy and reducing mask erosion in a patterned substrate placed in an inductively coupled plasma processing tool, in accordance with at least one embodiment of the present disclosure.

FIG. 8A illustrates a cross-sectional illustration of a mask formed above a substrate, in accordance with at least one embodiment of the present disclosure.

FIG. 8B illustrates a cross-sectional illustration of a trench profile of a high aspect ratio trench formed in a substrate, in accordance with at least one embodiment of the present disclosure.

FIGS. 9A-D illustrate plots of ion energy distribution functions in plasma sheaths resulting from single voltage level and dual voltage level discharges generated by a non-sinusoidal continuous wave voltage source, in accordance with at least one embodiment of the present disclosure.

FIGS. 10A-D are cross-sectional illustrations of simulations of trenches formed in a silicon substrate corresponding to different voltage biasing conditions on an electrostatic chuck, in accordance with at least one embodiment of the present disclosure.

FIGS. 11A-D are cross-sectional illustrations of simulated mask profiles corresponding to different voltage biasing conditions on the electrostatic chuck following processes to etch trenches, in accordance with at least one embodiment of the present disclosure.

FIG. 12 illustrates a processor system with machine-readable storage medium having instructions that when executed cause the processor to control spread in ion energy, in accordance with at least one embodiment of the present disclosure.

### DETAILED DESCRIPTION

A method to enhance etch rate and improve critical dimension of features and mask selectivity in an inductively coupled plasma is described. Here, numerous specific details are set forth, such as structural schemes to provide a thorough understanding of at least one embodiment. It will be apparent to one skilled in art that at least one embodiment may be practiced without these specific details. In other instances, well-known features, such as radio frequency sources, are described in lesser detail to not unnecessarily obscure at least one embodiment. Furthermore, it is to be understood that at least one embodiment shown in figures are illustrative representations and are not necessarily drawn to scale.

In some instances, well-known methods and devices are shown in block diagram form, rather than in detail, to avoid obscuring at least one embodiment. Reference throughout this specification to “an embodiment” or “one embodiment” or “some embodiments” or “at least one embodiment” means that a particular feature, structure, function, or characteristic described in connection with an embodiment is included in at least one embodiment. Thus, appearances of phrase “in an embodiment” or “in one embodiment” or “at least one embodiment” or “some embodiments” in various places throughout this specification are not necessarily referring to a same embodiment. Furthermore, particular features, structures, functions, or characteristics may be combined in any suitable manner in at least one embodiment. For example, a first embodiment may be combined with a second embodiment anywhere particular features, structures, functions, or characteristics associated with first embodiment and second embodiment are not mutually exclusive.

Here, “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical, electrical or in magnetic contact with each other, and/or that two or more elements co-operate or interact with each other (e.g., as in a cause an effect relationship).

Here, “over,” “under,” “between,” and “on” as used herein refer to a relative position of one component or material with respect to other components or materials where such physical relationships are noteworthy. Unless these terms are modified with “direct” or “directly,” one or more intervening components or materials may be present. Similar distinctions are to be made in context of component assemblies. As used throughout this description, and in claims, a list of items joined by “at least one of” or “one or more of” can mean any combination of listed terms.

Here, “adjacent” may generally refer to a position of a thing being next to (e.g., immediately next to or close to with one or more things between them) or adjoining another thing (e.g., abutting it).

Unless otherwise specified in explicit context of their use, terms “substantially equal,” “about equal” and “approximately equal” may mean that there is no more than incidental variation between two things so described. In at least one embodiment, such variation is typically no more than +/−10% of a referred value.

Plasma etching is indispensable for modern day semiconductor device manufacturing. Here “plasma etching” may generally refer to as a process of removing materials from a surface by charged particles and or reactive species generated by a plasma. In at least one embodiment, plasmas can be utilized to etch masked material as well as maskless structures during fabrication of semiconductor devices. In at least one embodiment, etching masked materials include forming a photoresist mask over material and using patterns in mask to etch material below, selectively to mask. In at least one embodiment, etching maskless structures include removing some or all material formed in pockets selectively to surrounding material or forming spacers on sidewalls of gate electrodes in transistors.

There are various types of tools that generate and sustain plasma, called plasma etch process tools. Here “plasma etch process tools” may generally refer to an apparatus that utilizes a plasma to generate ions and reactive species to etch a material. Here, “plasma” may generally refer to a collection of ionized gases that are electrically neutral. In at least one embodiment, plasma etch process tools can generate plasma by transformer action, electron cyclotron resonance, or capacitive methods. In at least one embodiment, wafers, that include materials to be etched, are transported under vacuum conditions to an electrostatic chuck that is housed within a plasma processing chamber or plasma chamber. Here, “wafer” may generally refer to a substrate that is either conductive or insulative and includes one or more materials that are dielectric, insulative, metallic, or semi-conducting. Here, “electrostatic chuck” may generally refer to a support structure that utilizes electrostatic clamping between wafers and an uppermost surface of chuck.

In at least one embodiment, a gas mixture is flowed into a chamber and a plasma is turned on by one of methods above. In at least one embodiment, a plasma is formed in a vicinity of a wafer that is placed on an electrostatic chuck. In at least one embodiment, energetic electrons produced after striking a plasma, create reactive radical species and ions by dissociation of gas mixture (known as feedstock gas). In at least one embodiment, plasmas used for processing are weakly ionized, in that a density of ions and electrons are a fractional portion of neutral atoms in plasma. In at least one embodiment, plasmas are quasi neutral, where density of electrons is approximately equal to density of ions. In at least one embodiment, among ions and electrons that are produced within a plasma, electrons are more mobile, and escape from edges of plasma to chamber walls and wafer surface. Loss of electrons at plasma edge leads to formation of a plasma sheath at an edge. Here, “plasma sheath or sheath” may generally refer to a region of net positive charge density at an edge of plasma.

In at least one embodiment, plasma may have three regions, a bulk region where an electrical potential can be positive but small, for example less than 50 V and a pre-sheath region between a bulk region and a sheath region. In at least one embodiment, plasma potential at pre-sheath/sheath boundary is close to zero and drops to a negative value near a wall or a wafer surface. In at least one embodiment, sheath region acts as a potential hill for electrons and a valley for ions. In at least one embodiment, ions enter sheath at sheath/presheath boundary with a velocity, which is defined by an ion temperature in bulk plasma. In at least one embodiment, ions accelerate towards wafer surface which is at a lower potential relative to sheath/presheath boundary.

In at least one embodiment, ions striking a wafer surface are utilized in processing plasmas to etch feature profiles in semiconductor, dielectric and conductive materials that may be deposited on wafer surface. In at least one embodiment, understanding and controlling ion energy at wafer surface is advantageous to enable fine control of processes utilized to a variety of etch features to fabricate semiconductor devices. In at least one embodiment, a relatively thin sheath (e.g., less than 10 mm) and low-pressure discharge (e.g., less than 0.1 Pa) can result in a collisionless sheath which can be used to reduce ion angular spread at a wafer surface. In at least one embodiment, a collisionless sheath is one where a sheath thickness is substantially smaller than an ion mean free path in a sheath. Here, “ion angular spread” may generally refer to a spread of angles that ions, with a given energy, have at a wafer surface. In at least one embodiment, ions transiting through plasma sheath on their way to wafer surface have an ion energy distribution that can be small but not zero. Here, “ion energy distribution” may generally refer to distribution of ions arriving at a wafer surface after exiting a plasma.

Ion energy distribution can result due to oscillations in plasma and in due to oscillations in sheath potential and influenced by oscillation frequency. In at least one embodiment, ion energy distributions can be tuned by superposing an externally driven time varying voltage at electrostatic chuck.

In at least one embodiment, inductively coupled plasma can offer advantages over plasma generated by other methods in that ion energies at a wafer surface can be independently controlled from ion temperatures in a plasma. Here, “inductively coupled plasma” may generally refer to a plasma that is generated and sustained by a transformer action external to chamber. In at least one embodiment, plasma potential and ion temperature are directly controlled by power delivered through a transformer action. In at least one embodiment, ion temperatures can be controlled by transformer coupling that induces an electric field within an etch chamber. Here, “etch chamber” may generally refer to a chamber where plasmas are produced and wafers are plasma etched. In at least one embodiment, induced electric field helps to ignite and sustain plasma and control global parameters such as electron and ion temperatures, densities etc. Plasma etch and deposition systems include electrostatic chucks. Here, “electrostatic chuck” may generally refer to a support structure, within etch chamber, where wafers or substrates for processing are placed. In at least one embodiment, wafers come into contact with a plasma sheath at an edge of a plasma boundary during processing. In at least one embodiment, ions exit a sheath with a spread in ion energy and ion angular spread. In at least one embodiment, ion energies are controlled by a bulk plasma potential but can also be controlled by biasing electrostatic chuck.

In at least one embodiment, electrostatic chuck includes a conductive electrode and an insulator layer on conductive electrode, where a substrate typically rests. In at least one embodiment, electrostatic chuck is typically voltage biased by a radio frequency (RF) voltage waveform to induce an RF voltage on wafer. In at least one embodiment, RF voltage induced on wafer overcomes capacitive effects of insulator. In at least one embodiment, tuning RF voltage waveform overcomes a steady rise in potential at wafer due to a steady ion flux. In at least one embodiment, RF biasing an electrostatic chuck can also change a sheath voltage. In at least one embodiment, low pressure discharges, typical of inductively coupled plasmas, sheath may be generally considered to be collisionless and relatively narrow (e.g., in order of a couple of millimeters). As bias voltage approaches kV level, for instance, in dielectric chambers, sheath may become collisional. In at least one embodiment, plasma potential in bulk may also be considered to have low levels of voltage fluctuation.

In at least one embodiment, ion energy, and more precisely ion energy distribution at wafer depends on (a) time varying flux of ions entering sheath and on (b) a time varying sheath voltage. If (b) is more predominant then voltage oscillations in sheath may be primarily due to frequency of RF voltage waveform biasing an electrostatic chuck. In at least one embodiment, response of ions to RF voltage waveform influences etching characteristics on a wafer surface. In at least one embodiment, in addition to voltage amplitude, oscillation frequency is also useful to influence etching characteristics. In at least one embodiment, magnitude of voltage and frequency of oscillations can shape ion energy distributions as well as ion angular spread at a wafer surface. While former can control etch rates, latter can influence shapes of different features etched. In at least one embodiment, ions traverse a sheath over a finite time period. In at least one embodiment, this is determined by initial ion velocity, determined by an ion temperature as they enter sheath, and a sheath thickness. In at least one embodiment, sheath thickness also changes with oscillating voltage amplitude and on oscillation frequency. In at least one embodiment, ion energy distribution is highly dependent on a time scale over which voltage amplitude changes.

In at least one embodiment, programming time varying voltage amplitude within sheath region can advantageously provide a pathway to reduce an angular spread in ions exiting plasma. In at least one embodiment, reducing angular spread can positively influence etching parameters such as etch anisotropy or a degree of vertical etching to lateral etching. In at least one embodiment, reducing ion angular spread can be useful for anisotropic etching high aspect ratio features during semiconductor device fabrication. Aspect ratio is defined as a ratio between depth:width of a feature. In at least one embodiment, high aspect ratio (such as aspect ratio that is greater than 20:1) features include trenches. In at least one embodiment, trenches can have a width ranging between 10 nm and 20 nm and depth of at least 200 nm. In at least one embodiment, obtaining substantially vertical sidewalls in trenches can advantageously provide a structure to fabricate capacitors with enhanced electrical features or to fabricate source and drain isolation regions in transistors.

In at least one embodiment, ion angular spread at a wafer surface may be proportional to square root of ion temperature in bulk plasma and inversely proportional to square root of sheath voltage Vₛ. In at least one embodiment, one approach to reduce ion angular spread may be to enhance bias power on electrostatic chuck. Increasing biasing voltage increases Vₛ and reduces ion angular spread. In at least one embodiment, pulsed DC-like voltage waveforms can be used to reduce ion energy distribution to improve etch characteristics such as uniformity and anisotropy. In at least one embodiment, pulsed DC-like voltage signal is a non-sinusoidal continuous wave voltage (NSCWV) signal. Here, “non-sinusoidal continuous wave voltage” may generally refer to a continuous electrical pulse that has periodicity but where amplitude is characterized by non-monotonically increasing or decreasing shape.

In at least one embodiment, NSCWV signal has a frequency range between, for example, 100 KHZ and 400 KHz. In at least one embodiment, a low frequency signal (e.g., less than 400 KHz) ensures that it is not blocked by a capacitance of an insulator layer present between wafer and electrostatic chuck electrode (e.g., electrostatic chuck). In at least one embodiment, magnitude of NSCWV signal can also be tuned to provide an effective voltage that overcomes an increase in ion current on wafer during operation. In at least one embodiment, NSCWV signal is different from regular RF waveform. In at least one embodiment, RF waveforms have a defined oscillation frequency and peak amplitudes that oscillate. In at least one embodiment, NSCWV signals can include multiple voltage ramps, as will be discussed below.

Reducing a spread in ion energy without lowering absolute voltage levels in NCSWV waveforms may not be beneficial. Masks utilized to pattern trenches can become eroded when ions continuously bombard a wafer surface, even if there is a distribution of ion energies. Simply lowering absolute voltage levels can slow down etch rates but this can also potentially reduce etch anisotropy, e.g., become more isotropic.

In at least one embodiment, NCSWV waveforms have been superposed with a high frequency RF bias to provide a combined voltage pulse to electrostatic chuck. In at least one embodiment, high frequency RF bias has a frequency that is above, for example, 1 MHZ. In at least one embodiment, above 1 MHz, ions transiting a sheath may experience many cycles of voltage oscillations such that ions respond to a time averaged sheath voltage. In at least one embodiment, time averaged sheath voltage has a magnitude that depends on a magnitude of applied voltage bias. In at least one embodiment, a time averaged sheath voltage corresponding to high frequency RF bias may not have same effect as NCSWV waveforms. In at least one embodiment, ion energy distribution in high frequency RF bias modulated sheaths can have a greater ion energy distribution. but ions in an NCSW sheath can have a very narrow energy spread. In at least one embodiment, application of NCSWV wave form alone can be advantageously utilized for etching.

In at least one embodiment, with an NSCWV signal, ion distribution can be tightened, and hence etch anisotropy can be controlled. But to also reduce mask damage, a dual voltage pulsing sequence may be implemented, in accordance with at least one embodiment. In at least one embodiment, a dual voltage pulsing sequence includes changing voltage levels between two voltage levels. In at least one embodiment, a higher voltage level can be used to reduce ion energy distribution, increase anisotropy, and preserve etch rate. In at least one embodiment, a lower voltage may be used to give mask a relaxation time by reducing continuous high energy ion bombardment. In at least one embodiment, higher voltage level may be part of a first voltage envelope lasting for a first finite duration. In at least one embodiment, higher voltage level may be measured with respect to a first reference voltage.

In at least one embodiment, within first voltage envelope, higher voltage level is attained during a first portion of a first pulse train. In at least one embodiment, additional features of first pulse train include a second portion comprising a gradually ramped voltage phase and a third portion that is at first reference voltage. In at least one embodiment, first and second portions of first pulse train may have a larger duty cycle than third portion. In at least one embodiment, first portion of a first pulse train is designed to reduce ion angular spread. In at least one embodiment, ramped voltage phase may be designed to counter an increase in ion current at wafer substrate. Here, “duty cycle” may generally refer to ratio of time an NSCWV signal is at a first defined voltage level compared to a time NSCWV signal is at a second defined voltage level. In at least one embodiment, first voltage may be finite, both positive or negative, and second voltage may be finite, both positive, negative or zero.

In at least one embodiment, lower voltage level may be part of a second voltage envelope lasting for a second finite time duration. In at least one embodiment, lower voltage level may be measured with respect to a second reference voltage. In at least one embodiment, within a second voltage envelope, lower voltage level may be attained during a first portion of a second pulse train. In at least one embodiment, additional features of second pulse train includes a second portion comprising a gradually ramped voltage phase and a third portion that is at second reference voltage. In at least one embodiment, first and second portions of second pulse train may have a larger duty cycle than third portion. In at least one embodiment, first portion of a second pulse train may be designed to reduce ion bombardment providing some respite to mask. In at least one embodiment, ramped voltage phase may be designed to counter an increase in ion current at wafer substrate.

In at least one embodiment, dual voltage pulsing sequence may have a duty cycle that favors first voltage envelope over second voltage envelope. In at least one embodiment, first and second reference levels may be at a same level or at different levels. In at least one embodiment, difference between higher voltage level and first reference voltage may be larger than a difference between lower voltage level and second reference voltage.

While NCSWV waveform has been described with regards to implementation in an inductively coupled plasma, it can also be implemented generally in other plasma processing tools, in accordance with at least one embodiment.

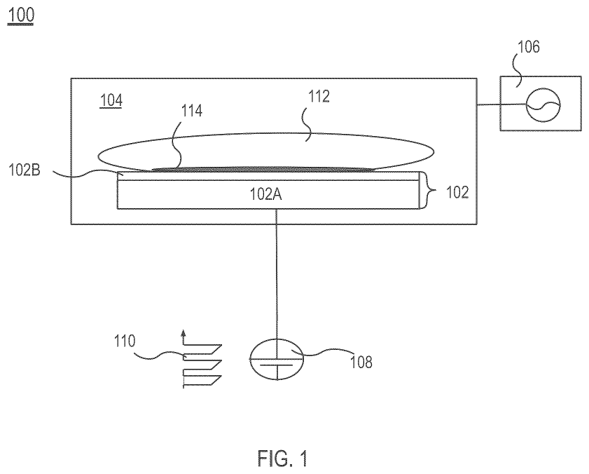

FIG. 1 illustrates a schematic of a plasma processing tool 100, in accordance with at least one embodiment. In at least one embodiment, plasma processing tool 100 is an example of an inductively coupled etch tool, that includes an electrostatic chuck 102 within process chamber 104 and an RF generator 106 coupled with coils above process chamber 104. In at least one embodiment, plasma processing tool 100 may further include a non-sinusoidal continuous wave voltage (NSCWV) generator 108 coupled in series with electrostatic chuck 102.

In at least one embodiment, electrostatic chuck 102 includes an electrode plate 102A coupled with NSCWV generator 108, and an insulator 102B on electrode plate 102A. In at least one embodiment, insulator 102B may include dielectric materials including alloys and ceramics such as alumina (Al₂O₃), silicon dioxide (SiO₂), silicon nitride (Si₃N₄), and sapphire.

In at least one embodiment, NSCWV generator 108 may be configured to produce a pulsed voltage waveform 110 at electrostatic chuck 102. In at least one embodiment, NSCWV generator 108 can generate a peak voltage of up to 100 kV. In at least one embodiment, NSCWV generator 108 may be configured to produce a voltage in range of 2 kV to 10 kV. In at least one embodiment, NSCWV generator 108 can generate voltage pulses in range of 50 kHz and 500 kHz.

In at least one embodiment, during operation, plasma 112 may be generated within process chamber 104. In at least one embodiment, ions are ejected from a plasma sheath, an outmost portion of plasma 112 that may be at vicinity of insulator 102B. In at least one embodiment, plasma sheath may be a non-neutral region formed at a plasma boundary to balance electron and ion losses to maintain quasi-neutrality. In at least one embodiment, ions impinge on to substrate 114 placed on electrostatic chuck 102 and perform a variety of etching (e.g., chemical, mechanical etc.) of one or materials within substrate 114.

In at least one embodiment, characteristics of ions (e.g., velocity and angular distribution) within a sheath region of plasma 112 may depend on (a) plasma potential and (b) potential at surface of substrate 114, which may be controlled by a voltage applied to electrostatic chuck 102. In at least one embodiment, velocity of ions may be directly influenced by both (a) and (b) because an increase in both (a) and (b) increases an electric field that drives ions towards electrostatic chuck 102. In at least one embodiment, electric field in a bulk portion of plasma may be substantially small (e.g., 10V/cm or less) but field in a sheath region (e.g., adjacent to substrate 114) can be between 1 KV/cm.

In at least one embodiment, when pulsed voltage waveform 110 may be applied to electrostatic chuck by NSCWV generator 108, plasma sheath oscillates in response to pulsed voltage waveform 110. In at least one embodiment, application of pulsed voltage waveform 110 changes width (and potential) of sheath. In at least one embodiment, changes in sheath width or sheath-pre sheath boundary relative to substrate 114 may be defined by rapid oscillations of sheath width at this boundary in response to a frequency of pulsed voltage waveform 110. In at least one embodiment, because ions are significantly less mobile than electrons, ions respond slowly and over a time that is averaged over a frequency of pulsed voltage waveform 110. In at least one embodiment, slower response may cause a spread in an ion energy, or alternatively may cause an ion energy distribution. In at least one embodiment, oscillations in sheath can be due to oscillations arising from an inductive electric field that drives plasma oscillations in bulk plasma, as well as from pulsed voltage waveform 110 that is applied to electrostatic chuck 102. In at least one embodiment, for purposes of influencing ion distribution in inductively coupled plasma systems, pulsed voltage waveform 110 plays a substantially dominant role in terms of impact due to voltage oscillations. In at least one embodiment, form of pulsed voltage waveform 110 and effects on etching features and mask within substrate 114 are described in detail below.

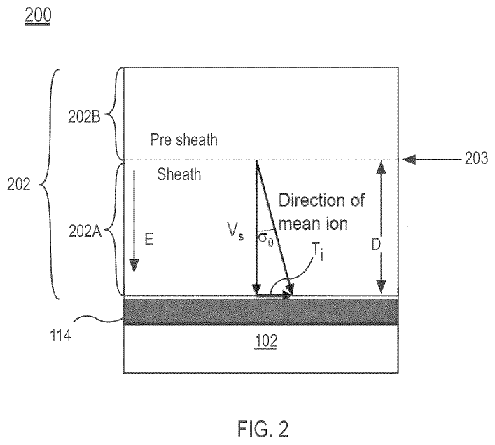

A relationship between temperature of ions in plasma 112, voltage applied to sheath 202A, and angular spread is illustrated in a diagram 200 in FIG. 2, in accordance with at least one embodiment. In at least one embodiment, plasma 202 includes a sheath 202A and presheath 202B adjacent to sheath 202A. In at least one embodiment, voltage at ion at a boundary 203 between sheath 202A and presheath 202B, relative to voltage Vₛ. supplied to a surface of substrate 114 creates a net electric field, E, in sheath 202A. In at least one embodiment, voltage Vₛ, also determines a thickness, D, of sheath 202A. In at least one embodiment, electric field, E, is a function of power coupled to sustaining plasma 112 and raises a potential of plasma to levels used to sustain plasma. In at least one embodiment, electric field, E, is directed towards electrostatic chuck 102. In at least one embodiment, lateral component of ion velocity due to Tᵢ arises from random motion of ions in plasma. In at least one embodiment, a vector sum of ion velocity due to Tᵢ and velocity due to Vₛ provides a maximum ion angular spread, sigma theta.

In at least one embodiment, a relationship between temperature of ions, voltage supplied to ions within sheath, and of angular spread in ion velocity illustrated in FIG. 2, is expressed by equation 1.1:

$$Sigma theta = {Tan}^{- 1} [ Square root ( {T}_{i} / {e V}_{s} ) ] , \qquad ( 1.1 )$$

where sigma theta is an angular spread, Tᵢ is temperature of ions, and Vₛ is a sheath voltage of plasma sheath of plasma 112 within process chamber 104 (FIG. 1).

In at least one embodiment, angular spread, theta, of ions accelerating towards an electrostatic chuck 102, is directly influenced by a ratio between Tᵢ, Vₛ. In at least one embodiment, voltage Vₛ is set by a pulsed voltage applied to electrostatic chuck 102. In at least one embodiment, methods to increase Vₛ without increasing Tᵢ are highly desirable to control ion energy and ion angular spreads. In at least one embodiment, in an ICP, transformer action that couples RF power from RF generator 106 (FIG. 1) determines plasma potential and consequently Tᵢ.

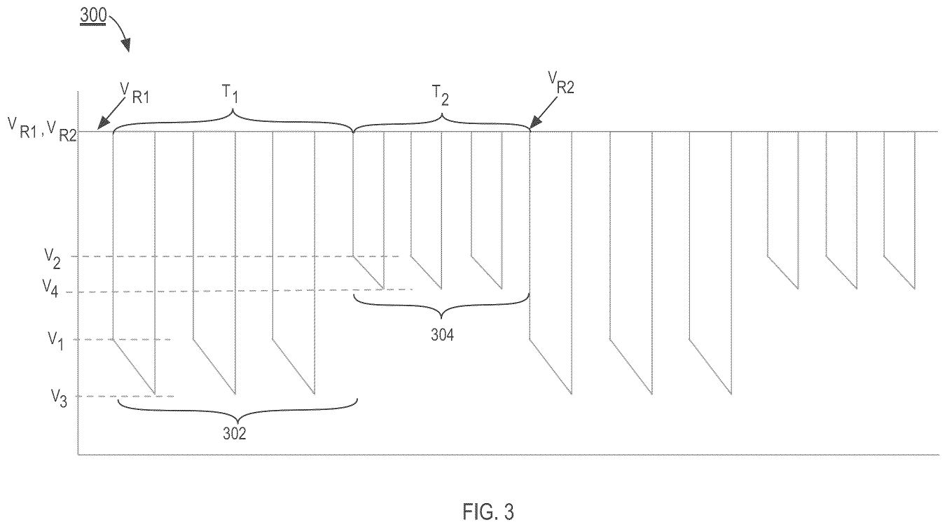

FIG. 3 illustrates a schematic of a pulsed voltage waveform 300 generated by NSCWV generator 108 (FIG. 1), in accordance at least one embodiment. In at least one embodiment, generating a pulsed voltage waveform 300 includes generating an NSCWV signal 302 for a first time duration T₁, of a clock cycle. NSCWV signal 302 comprises a first base voltage V₁ and a frequency, f₁. In at least one embodiment, as shown while T₁ comprises three pulses, number of pulses is arbitrary.

In at least one embodiment, generating pulsed voltage waveform 300 further includes performing a transition that includes changing from generating NSCWV signal 302 to generating an NSCWV signal 304. In at least one embodiment, NSCWV signal 304 is generated for a time duration, T₂ of clock cycle. In at least one embodiment, NSCWV signal 304 comprises a second base voltage V₂ and a frequency, f₂. As shown while T₂ comprises three pulses, number of pulses is arbitrary.

In at least one embodiment, generating pulsed voltage waveform 300 further includes performing a second transition comprising changing from NSCWV signal 304 back to NSCWV signal 302. In at least one embodiment, first transition and second transition are repeated over clock cycle. Here, “clock cycle” may generally refer to a total time period of duration of pulsed voltage waveform 300. In at least one embodiment, by transitioning between V₁ and V₂ pulsed voltage waveform 300 may be an example of a level-to-level voltage pulse.

In at least one embodiment, for purposes of controlling ion energies and distribution, a difference between V₁ and a first reference voltage V_{R1}, and a difference between V₂ and a second reference voltage V_{R2} is useful. In at least one embodiment, difference, |V₁−V_{R1}| and difference |V₁−V_{R2}| is useful. In at least one embodiment, V_{R1} and V_{R2} may be different. In at least one embodiment, V_{R1} is substantially same as V_{R2}. In at least one embodiment, predominant characteristics of pulsed voltage waveform 300 is that |V₁−V_{R1}| is greater than |V₁−V_{R2}|.

In at least one embodiment, differences between |V₁−V_{R1}| and |V₁−V_{R2}| directly manifest in differences in ion energy distribution and subsequently etching of features in substrate 114 (FIG. 1).

In at least one embodiment, an inverse of a sum of first time duration, T₁ and second time duration, T₂, defines a duty cycle of pulsed voltage waveform 300. In at least one embodiment, duty cycle of NSCWV signal 302 is between at least 50-75%. In at least one embodiment, T₂ may be less than T₁. In at least one embodiment, T₂ can be greater than T₁. In at least one embodiment, duty cycle of NSCWV signal 302 determines how long plasma discharge will be used to produce a high etching rate phase versus a lower etching rate phase.

In at least one embodiment, sum of first time duration and second time duration, i.e, T₁+T₂, defines a pulse frequency fₚ of pulsed voltage waveform 300. In at least one embodiment, fₚ is between 1 Hz and 100 kHz. In at least one embodiment, fₚ cannot be less than f₁ and f₂.

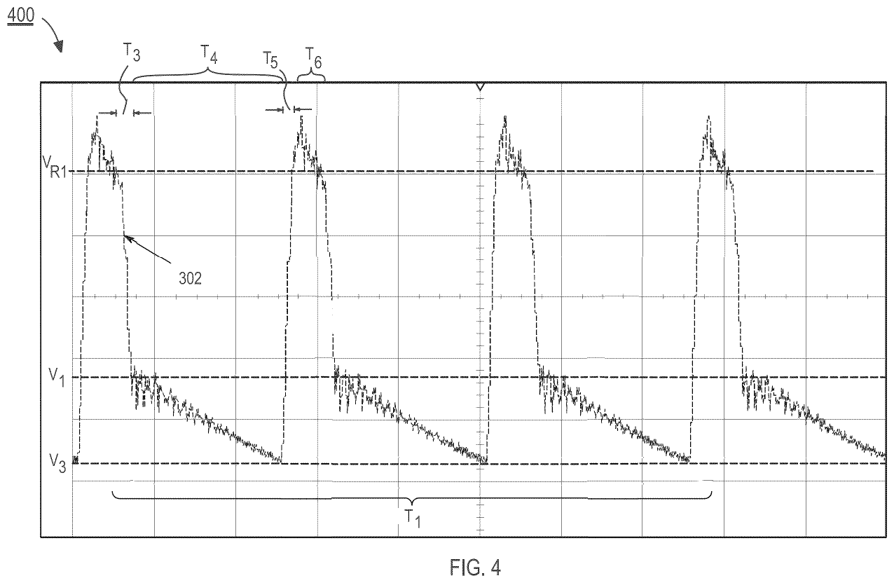

FIG. 4 illustrates a plot 400 of an actual applied first NSCWV signal 302, in accordance with at least one embodiment. In at least one embodiment, NSCWV generator 108 described in association with FIG. 1 may be utilized to generate NSCWV signal 302. In at least one embodiment, referring again to FIG. 4, applying or generating NSCWV signal 302 includes performing a first operation comprising increasing a magnitude of voltage level from a first reference voltage V_{R1} to first base voltage V₁ over a first time interval, T₃. In at least one embodiment, V_{R1}, is a “zero level.” In at least one embodiment, V_{R1}, can be a positive voltage level. In at least one embodiment, first time interval, T₃ may be quasi-instantaneous.

In at least one embodiment, a second operation is performed where magnitude of voltage level is ramped from first base voltage V₁ to a first peak voltage V₃ over a second time interval, T₄. In at least one embodiment, magnitude of V₃ is greater than a magnitude of V₁. In at least one embodiment, magnitude of V₃ is between 25-50% percent greater than a magnitude of V₁. In at least one embodiment, an individual harmonic is an integer multiple of a fundamental frequency such as 400 kHz. In at least one embodiment, NSCWV signal 302 includes up to (and including) tenth harmonic (for example, 4000 kHz). In at least one embodiment, ramp down from V₁ to V₃ includes low frequency oscillations from 400 kHz-4000 kHz because of super position between different harmonics.

In at least one embodiment, generating NSCWV signal 302 further includes performing a third operation comprising decreasing voltage level from first peak voltage V₃ to reference voltage V_{R1}, over a third time interval, T₅. In at least one embodiment, magnitude of V₃ is greater than a magnitude of V_{R}. In at least one embodiment, T₅ may be quasi-instantaneous.

In at least one embodiment, generating NSCWV signal 302 further includes performing a fourth operation comprising maintaining voltage level at reference voltage V_{R1}, for a fourth time interval T₆. In at least one embodiment, voltage overshoots to a positive voltage.

In at least one embodiment, first operation, second operation, third operation and fourth operation constitute a single cycle of NSCWV signal 302 and are repeated over first time duration T₁.

In at least one embodiment, NSCWV signal 302 has a frequency f₁, that is equal to 1 divided by a sum of first time interval T₃, second time interval T₄, third time interval T₅, and fourth time interval T₆. In at least one embodiment, frequency f₁, may be less than 100 KHz. In at least one embodiment, a ratio between second time interval T₄ to fourth time interval T₆ is greater than or equal to 2:1. In at least one embodiment, a ratio between second time interval T₄ to fourth time interval T₆ is equal to 3:1. In at least one embodiment, NSCWV signal 302 has a duty cycle, where a non-zero negative voltage portion (below V_{R1}) that is greater than 50 and less than 100. In at least one embodiment, NSCWV signal 302 has a duty cycle that is 75%. In at least one embodiment, second time interval T₄, is greater than first time interval T₃, or third time interval T₅, by a factor of at least 100.

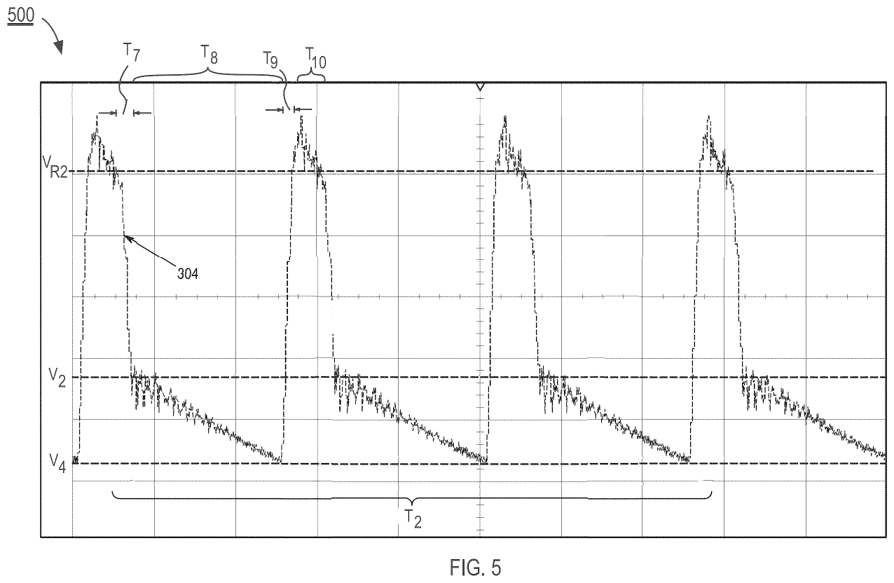

FIG. 5 illustrates a plot 500 of an actual applied NSCWV signal 304, in accordance with at least one embodiment. In at least one embodiment, NSCWV generator 108 described in association with FIG. 1 may be utilized to generate NSCWV signal 304. Referring again to FIG. 5, in at least one embodiment, applying or generating NSCWV signal 304 includes performing a fifth operation comprising increasing a magnitude of voltage level from a second reference voltage V_{R2} to first base voltage V₂, over a first time interval T₇. In at least one embodiment, V_{R2}, is a “zero level.” In at least one embodiment, V_{R2}, can be a positive voltage level. V_{R2} may be same or different from V_{R1} (FIG. 4). In at least one embodiment, first time interval T₇ may be quasi-instantaneous.

In at least one embodiment, a second operation is performed where magnitude of voltage level is ramped from first base voltage V₂ to a first peak voltage V₄ over a second time interval T₈. In at least one embodiment, magnitude of V₄ is greater than a magnitude of V₂, as shown. In at least one embodiment, magnitude of V₄ is between 25-50% percent greater than a magnitude of V₂. In at least one embodiment, an individual harmonic is an integer multiple of a fundamental frequency such as 400 kHz. In at least one embodiment, NSCWV signal 304 includes up to and including tenth harmonic (for example 4000 kHz). In at least one embodiment, ramp down from V₂ to V₄ includes low frequency oscillations from 400 kHz to 4000 kHz because of super position between different harmonics.

In at least one embodiment, generating NSCWV signal 304 further includes performing a third operation comprising decreasing voltage level from first peak voltage V₄ to a second reference voltage V_{R2}, over a third time interval, T₉. In at least one embodiment, magnitude of V₄ is greater than a magnitude of V_{R2}. In at least one embodiment, third time interval, T₉ may be quasi-instantaneous. In at least one embodiment, second time interval T₈, is greater than first time interval, T₇, or third time interval, T₉, by a factor of at least 100.

In at least one embodiment, generating NSCWV signal 304 further includes performing a fourth operation comprising maintaining voltage level at reference voltage V_{R2}, for a fourth time interval, T₁₀. In at least one embodiment, voltage overshoots to a positive voltage.

In at least one embodiment, first operation, second operation, third operation and fourth operation constitute a single cycle of NSCWV signal 304, and are repeated over first time duration, T₁.

In at least one embodiment, NSCWV signal 304 has a frequency, f₁, that equal to 1 divided by a sum of first time interval T₇, second time interval T₈, third time interval T₉, and fourth time interval T₁₀. In at least one embodiment, frequency is less than 100 KHz. In at least one embodiment, a ratio between second time interval T₈ to fourth time interval T₁₀ is greater than or equal to 2:1. In at least one embodiment, a ratio between second time interval T₈ to fourth time interval T₁₀ is equal to 3:1. In at least one embodiment, NSCWV signal 304 has a duty cycle, where a non-zero negative voltage portion (below V_{R2}) that is greater than 50 and less than 100. In at least one embodiment, NSCWV signal 304 has a duty cycle that is 75%. In at least one embodiment, second time interval, T₈, is greater than first time interval, T₇, or third time interval, T₉, by a factor of at least 100. In at least one embodiment, T₇ is comparable to T₃ (FIG. 4) and T₉ is comparable to T₅ (FIG. 4).

In at least one embodiment, frequency, f₂ may not be equal to frequency, f₁. In at least one embodiment, depending on embodiments, f₂ can be greater than, equal to or less than f₁. In at least one embodiment, T₈ may or may not be comparable to T₄ (FIG. 4), and T₁₀ may or may not be comparable to T₆ (FIG. 4). In at least one embodiment, a ratio between T₄:T₈ can be at least 1:1. In at least one embodiment, ratio between T₄:T₈ is 3:1.

In at least one embodiment, voltage peak V₂ and V₃ may or may not be equal. In at least one embodiment, V₃ can have a greater magnitude that V₄ or vice versa. In at least one embodiment, ramp from V₁ to V₃ may correspond to a voltage slope chosen to compensate for a linear voltage increase across a blocking capacitor due to charge build up by positive ions bombarding electrostatic chuck 102 in FIG. 1. In at least one embodiment, blocking capacitor is not illustrated in FIG. 1 but may be located between NSCWV generator 108 and electrostatic chuck 102. In at least one embodiment, blocking capacitor may be an insulator 102B between electrode plate 102A and substrate 114.

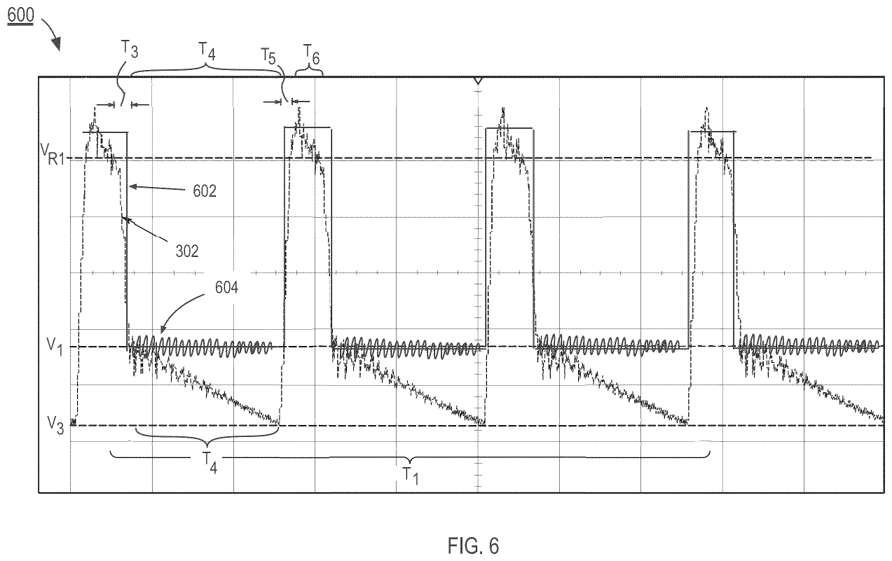

FIG. 6 illustrates a plot 600 of an induced voltage waveform 602 on a surface of a substrate (such as substrate 114 in FIG. 3), in accordance with at least one embodiment. In at least one embodiment, induced voltage waveform 602 is a result of a super position of NSCWV signal 302 and a voltage induced by ions leaving a sheath 202A impinging on surface of substrate 114 (FIG. 2). In at least one embodiment, during time interval, T₄, induced voltage waveform 602 is has an average voltage that is substantially constant and oscillations 604. In at least one embodiment, oscillations 604 are resultant from 400 kHz-4000 kHz signal produced by an NSCWV generator and arise from super-position between different harmonics described above. In at least one embodiment, NSCWV signal 302 generated by an NSCWV generator is superimposed for comparison. In at least one embodiment, ramp from V₁ to V₃ corresponds to a voltage slope chosen to compensate for a linear voltage increase due to charge build up by positive ions bombarding electrostatic chuck 102 (FIG. 1).

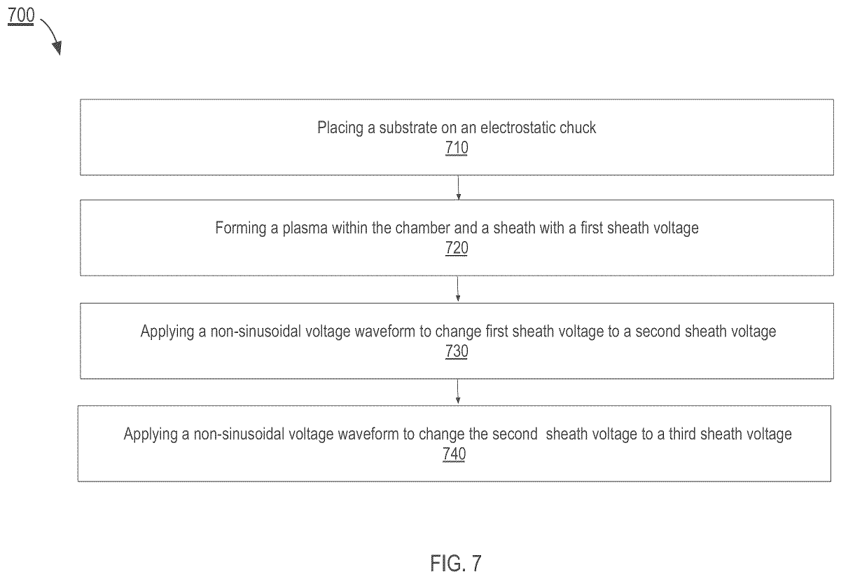

FIG. 7 illustrates a method 700 of changing ion energy and ion angular spread directed towards a surface of a substrate during an etch operation, in accordance with at least one embodiment. In at least one embodiment, some or all operations of method 700 may be performed or controlled by hardware, software, or a combination of them. In at least one embodiment, method 700 begins at operation 710 by placing a substrate on an electrostatic chuck within a plasma chamber. In at least one embodiment, electrostatic chuck is electrically coupled to an NSCWV generator. In at least one embodiment, method 700 continues at operation 720 by forming a plasma within plasma chamber, where plasma produces a sheath with a first sheath voltage. In at least one embodiment, method 700 continues at operation 730 by changing first sheath voltage to a second sheath voltage by applying a first NSCWV signal at electrostatic chuck. In at least one embodiment, first NSCWV signal comprises a first periodic function and creates a first voltage response on wafer substrate. In at least one embodiment, first voltage response effectuates a first change in a spread in ion energy at wafer due to change from first sheath voltage to second sheath voltage. In at least one embodiment, as sheath voltage is increased from first sheath voltage to second sheath voltage, ion energy is increased. In at least one embodiment, ion energy distribution is decreased and a high etch rate plasma is produced.

In at least one embodiment, method 700 concludes at operation 740 by changing second sheath voltage to a third sheath voltage by applying a second NSCWV signal at electrostatic chuck. In at least one embodiment, second non-sinusoidal voltage waveform comprises a second periodic function and creates a second voltage response on wafer substrate. In at least one embodiment, second voltage response effectuates a second change in a spread in ion energy at wafer due to change from second sheath voltage to a third sheath voltage. In at least one embodiment, as sheath voltage is decreased, ion energy is decreased. In at least one embodiment, ion energy distribution is decreased and a low etch rate plasma is produced.

In at least one embodiment, referring again to FIG. 4, pulsed voltage waveform 300 is applied to electrostatic chuck 102 (FIG. 1). In at least one embodiment, first sheath voltage is created at a wafer surface plasma boundary, immediately when plasma is produced. In at least one embodiment, a first non-sinusoidal voltage waveform, such as NSCWV signal 302, is applied at electrostatic chuck. In at least one embodiment, this creates a voltage response on wafer substrate that effectuates first change in a spread in ion energy at wafer. In at least one embodiment, second sheath voltage is averaged over a time period T₃+T₄.

Referring to FIG. 5, in at least one embodiment, pulsed voltage waveform 300 is applied to electrostatic chuck 102 (FIG. 1). In at least one embodiment, non-sinusoidal voltage waveform is changed from a first periodic function to a second periodic non-sinusoidal voltage waveform, such as NSCWV signal 304. In at least one embodiment, a lower magnitude base voltage V₂, in NSCWV signal 304 creates a voltage response on wafer that effectuates a second change in a spread in ion energy at wafer. In at least one embodiment, a lower magnitude V₂ compared to V₁ (FIG. 4) decreases ion energy distribution and reduces an etch rate but does not stop etching process. In at least one embodiment, third sheath voltage is averaged over a time period T₇+T₈.

In at least one embodiment, pulsed voltage waveform 300 described in association with FIG. 3 is applied to an electrostatic chuck to etch features with high aspect ratios selective to a mask formed on a wafer that is placed in electrostatic chuck.

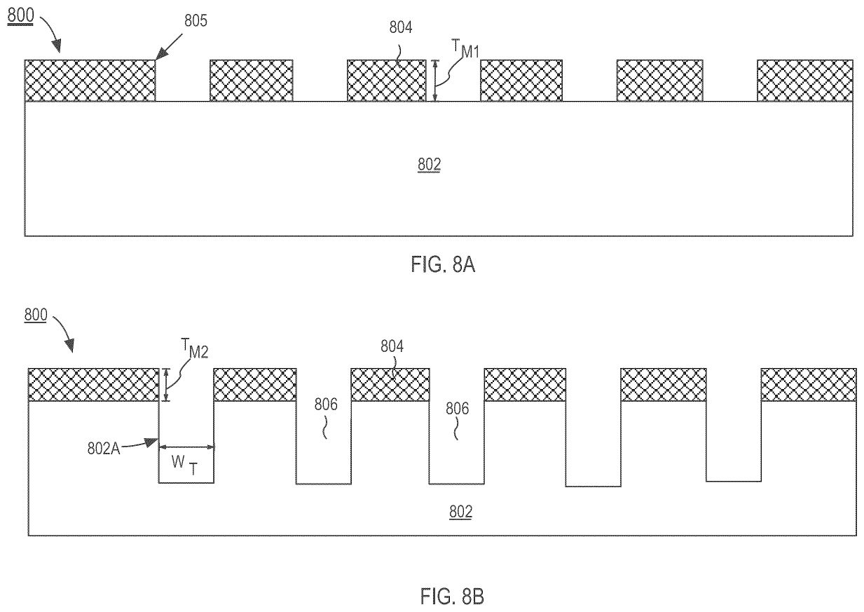

FIG. 8A is a cross-sectional illustration of a patterned wafer 800, in accordance with at least one embodiment. In at least one embodiment, patterned wafer 800 includes a substrate 802 and a mask 804 formed on substrate 802. In at least one embodiment, substrate 802 may include a single layer or multiple layers. In at least one embodiment, substrate 802 includes silicon, germanium, III-V, sapphire or quartz. In at least one embodiment, substrate 802 includes a dielectric formed on a silicon containing material. In at least one embodiment, mask 804 includes a photoresist material patterned by a lithographic process. In at least one embodiment, mask 804 includes a dielectric material that has been previously patterned by a lithographic process and followed by an etch process. In at least one embodiment, mask 804 has a thickness T_{M1}. In at least one embodiment, to preserve integrity of mask 804 during etch. In at least one embodiment, in particular erosion near edge 805 of mask, and extent of isotropic erosion can lead to flare in sidewalls of mask 804. In at least one embodiment, depending on rate of erosion of mask 804 compared to a targeted etch depth, upper portions of substrate 802 may become disadvantageously eroded. In at least one embodiment, it is desirable to balance control of ion energies, ion energy distribution, and directionality to pattern features with high fidelity.

FIG. 8B is a cross-sectional illustration of structure in FIG. 8A following process to plasma etch and form trenches in substrate 802, in accordance with at least one embodiment. In at least one embodiment, different waveforms can be generated by an NSCWV generator while etching substrate 802. In at least one embodiment, waveforms have same or substantially same characteristics as NSCWV signals 302 and 304 in pulsed voltage waveform 300 illustrated in FIG. 3, are generated by an NSCWV generator 108 (FIG. 1), to etch substrate 802.

In at least one embodiment, trenches 806 have substantially vertical sidewalls 802A. In at least one embodiment, substantially vertical sidewalls may enable devices to be fabricated with substantially uniform electrical characteristics. In at least one embodiment, mask 804 is substantially uniformly eroded to a new thickness T_{M2}, where T_{M2} is less than T_{M1}. In at least one embodiment, a balance between high energy etching, and low energy mask preservation operations may be implemented to form trenches 806.

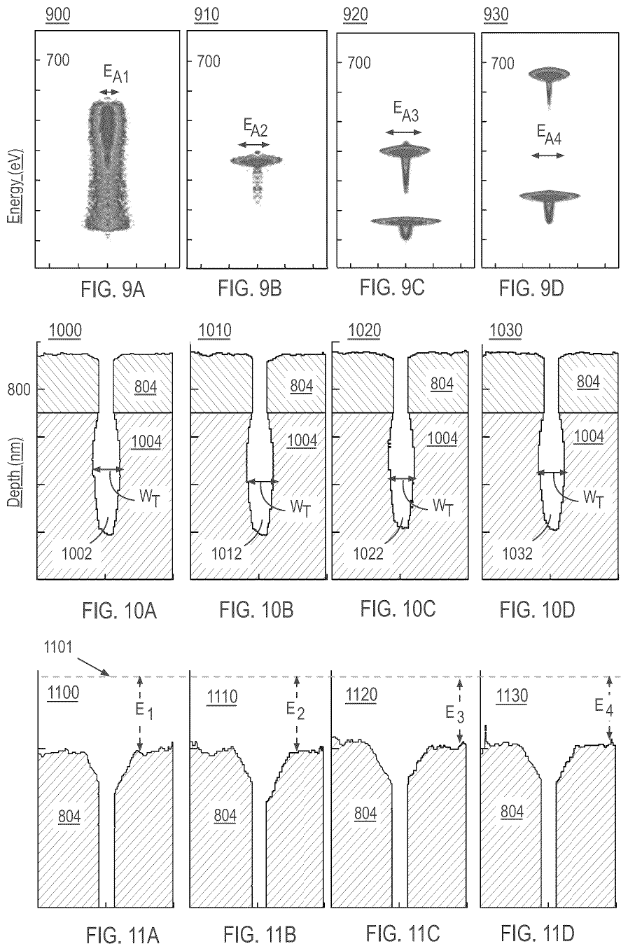

FIGS. 9A-9D illustrates simulations of ion angular spread as well as ion energy distribution at a wafer surface during processing in an ICP plasma for different applied voltages on an electrostatic chuck, in accordance with at least one embodiment. Vertical axis corresponds to energy of ions on and horizontal axis corresponds to ion angular spread (theta), measured in degrees.

FIG. 9A illustrates plot 900 of an ion angular spread resulting from an applied voltage of 330V generated by an RF generator. In at least one embodiment, an RF generator produces a sinusoidal voltage. In at least one embodiment, sinusoidal voltage has a peak voltage of V_{B}. In at least one embodiment, sinusoidal voltage may be shifted relative to a reference voltage. In at least one embodiment, magnitude of peak voltage for one voltage polarity will be |V_{B}|+|V_{shift}|, and peak voltage for an opposite polarity will be |V_{B}|−|V_{shift}|. In at least one embodiment, an ion angular spread E_{A1}, is approximately 3.32 degrees for a peak ion energy of 550 eV. In at least one embodiment, a sinusoidal bias voltage V_{b} produces 1.6-1.8V_{b} eV peak energy.

FIG. 9B illustrates plot 910 of an ion angular spread resulting from an applied voltage of 330V generated by a non-sinusoidal continuous wave voltage generator (such as NCSWV generator 108 in FIG. 1), in accordance with at least one embodiment. In at least one embodiment, an ion angular spread E_{A2}, is approximately 8.1 degree for a peak applied voltage of 330V. In at least one embodiment, a non-sinusoidal bias voltage V_{b-ns}, produces approximately 1 V_{b-ns} CV peak energy. In at least one embodiment, peak ion energy is approximately 370 eV.

FIG. 9C illustrates plot 920 of an ion angular spread resulting from a low level to a high-level pulsed voltage waveform generated by a non-sinusoidal continuous wave voltage generator (such as NSCWV generator 108 in FIG. 1), in accordance with at least one embodiment. In at least one embodiment, low level voltage is approximately 120V and high-level voltage is approximately 360V. In at least one embodiment, low-level voltage of 120V corresponds to V₂ (NSCWV signal 304) and high-level voltage of 360V corresponds to V₁ (NSCWV signal 302) in pulsed voltage waveform 300 illustrated in FIG. 3. In at least one embodiment, individual ion angular spread for a time period of NCSWV signal 304 is greater than an individual ion angular spread for a time period of NCSWV signal 302. In at least one embodiment, referring again to FIG. 9C, an average ion angular spread E_{A3} for high and low voltage levels is approximately 7.10 degrees. In at least one embodiment, ion angular spread is less than for an applied voltage of 330V illustrated in FIG. 9B. In at least one embodiment, peak energy is increased average angular spread decreases, as expected.

FIG. 9D illustrates plot 930 of an ion angular spread resulting from a low level to a high-level pulsed voltage waveform generated by a non-sinusoidal continuous wave voltage generator (such as non-sinusoidal continuous wave voltage generator 108 in FIG. 1), in accordance with at least one embodiment. In at least one embodiment, low level voltage is approximately 210V and high-level voltage is approximately 630V. In at least one embodiment, low-level voltage of 210V corresponds to V₂ (NSCWV signal 304) and high-level voltage of 630V corresponds to V₁ (NSCWV signal 302) in pulsed voltage waveform 300 illustrated in FIG. 3. In at least one embodiment, individual ion angular spread for a time period of NCSWV signal 304 is greater than an individual ion angular spread for a time period of a NCSWV signal 302. In at least one embodiment, referring again to FIG. 9D, an average ion angular spread E_{A4} for high and low voltage levels is approximately 6.6 degrees. In at least one embodiment, ion angular spread is less than for an applied voltage of 330V illustrated in FIG. 9B or for level-to-level applied voltage in FIG. 9C. In at least one embodiment, as peak energy is increased, average ion angular spread decreases as expected.

In at least one embodiment, etch profile, relative etch time and maximum trench width W_{T} are illustrated in FIGS. 10A-10D. In at least one embodiment, simulation results of etched trenches in a substrate that correspond to different pulsed voltage waveforms applied to chuck electrode, while etching trenches, are illustrated. Trenches illustrated in FIGS. 10A-10D are embodiments of trenches 806 formed in substrate 802, using mask 804 illustrated in FIG. 8B.

FIG. 10A is a cross-sectional illustration 1000 of an etch profile of trench 1002 formed in silicon substrate 1004 with mask 804, in accordance with at least one embodiment. In at least one embodiment, plasma etch process utilized to form trench 1002 corresponds to a voltage bias condition on chuck electrode described in association with FIG. 9A. In at least one embodiment, trench 1002 has an initial mask opening of 10 nm. In at least one embodiment, trench 1002 has a maximum width of 18.3 nm resulting from a peak ion angular spread of 3.32 degrees and an average ion angular spread of 7.7 degrees. In at least one embodiment, etch time utilized to etch an approximately 200 nm trench depth is normalized to time to.

FIG. 10B is a cross-sectional illustration 1010 of an etch profile of trench 1012 formed in silicon substrate 1004 with mask 804, due to an ion angular spread described in association with FIG. 9B, at least one embodiment. In at least one embodiment, trench 1012 has an initial mask opening of 10 nm. In at least one embodiment, trench 1012 has a maximum width W_{T}, of 18.8 nm resulting from a peak/average ion energy distribution of 8.1 degrees. In at least one embodiment, etch time of 1.05t₀ to etch approximately 200 nm of trench 1012 is greater than an etch time used to pattern trench 1002 (FIG. 10A), by approximately 5%.

FIG. 10C is a cross-sectional illustration 1020 of an etch profile of trench 1022 formed in silicon substrate 1004 with mask 804 due to an ion angular spread described in association with FIG. 9C, in accordance with at least one embodiment. In at least one embodiment, trench 1022 has an initial mask opening of 10 nm. In at least one embodiment, trench 1022 has a maximum width of 16.9 nm resulting from a peak ion energy distribution of 7.3 degrees and an average ion angular spread of 7.1 degrees. In at least one embodiment, etch time of 1.05t₀ is greater than an etch time used to pattern trench 1002 (FIG. 10A) by 5%.

In at least one embodiment, with a reduction in average angular spread to 7.1 degrees, maximum width W_{T}, is reduced. In at least one embodiment, etch rate compared to etching trench 1002 (FIG. 10A) is reduced, resulting in a greater etch time because of low voltage level pulsing added. In at least one embodiment, despite a higher-level voltage, because of additional low voltage level pulsing added, etch rate is substantially same as etch rate for etching trench 1012 (FIG. 10B).

FIG. 10D is a cross-sectional illustration 1030 of an etch profile of a trench 1032 formed in a silicon substrate 1004 with mask 804 due to an ion angular spread described in association with FIG. 9D, in accordance with at least one embodiment. In at least one embodiment, trench 1032 has an initial mask opening of 10 nm. In at least one embodiment, trench 1042 has a maximum width W_{T}, of 17 nm resulting from a peak ion angular spread of 6.02 degrees and an average ion angular spread of 6.6 degrees. In at least one embodiment, etch time of 0.95t₀ is less than an etch time used to pattern trench 1002 (FIG. 10A) by approximately 7%. In at least one embodiment, etch time of 0.95t₀ is less than an etch time used to pattern trenches 1012 and 1022 (FIGS. 10B and 10C, respectively) by approximately 11%.

In at least one embodiment, because of higher level voltage and an additional “higher” low voltage level pulsing added, etch rate is improved over etch rate for etching trench 1022 (FIG. 10C). In at least one embodiment, W_{T}, is approximately maintained at 17 nm.

In at least one embodiment, etch profile and mask erosion are illustrated in FIGS. 10A-10D. In at least one embodiment, different illustrations correspond to pulsed voltage waveform applied to chuck electrode while etching trench features in a substrate. Trenches illustrated in FIGS. 10A-10D are embodiments of trenches 806 formed in substrate 802, using mask 804 illustrated in FIG. 8B.

FIGS. 11A-11D are enhanced cross sectional illustrations of masks in FIGS. 10A-10D, in accordance with at least one embodiment. Trenches formed below an individual mask are not shown in illustrations. Each Figure corresponds to a respective pulsed voltage waveform applied to chuck electrode while etching trench features in a substrate, in accordance with at least one embodiment.

FIG. 11A is a cross-sectional illustration 1100 of mask 804 following process to etch and form trench 1002 in FIG. 10A, in accordance with at least one embodiment. In at least one embodiment, plasma etch process utilized to form trench 1002 corresponds to a voltage bias condition on chuck electrode described in association with FIG. 9A.

In at least one embodiment, referring again to FIG. 11A, dashed line 1101 represents a reference line of a top of mask 804 prior to etching trench 1002. In at least one embodiment, mask 804 is eroded during etching of trench. In at least one embodiment, mask 804 is eroded by an amount E₁. In at least one embodiment, as shown E₁ is normalized to 100% erosion.

FIG. 11B is a cross-sectional illustration 1110 of mask 804 following process to etch and form trench 1012 in FIG. 10B, in accordance with at least one embodiment. In at least one embodiment, plasma etch process utilized to form trench 1012 corresponds to a voltage bias condition on chuck electrode described in association with FIG. 9B.

Referring again to FIG. 11A, dashed line 1101 represents a reference line of a top of mask 804 prior to etching trench 1012. In at least one embodiment, mask 804 is eroded during etching of trench. In at least one embodiment, mask 804 is eroded by an amount E₂. As shown, E₂ is approximately 1.04 E₁. In at least one embodiment, a greater mask erosion is a result of a narrow energy band, but a wider ion angular spread compared to ion angular spread due to voltage bias condition on chuck electrode described in association with FIG. 9A.

FIG. 11C is a cross-sectional illustration 1120 of mask 804 following process to etch and form trench 1022 in FIG. 10C, in accordance with at least one embodiment. Plasma etch process utilized to form trench 1022 corresponds to a voltage bias condition on chuck electrode described in association with FIG. 9C.

Referring again to FIG. 11A, dashed line 1101 represents a reference line of a top of mask 804 prior to etching trench 1022. In at least one embodiment, mask 804 is eroded by an amount E₃. As shown, E₃ is approximately 0.88 E₁. In at least one embodiment, reduced erosion of mask 804 is a result of a level-to-level pulsed voltage waveform (such as pulsed voltage waveform 300 in FIG. 3). In at least one embodiment, high energy etching is prevalent during a higher voltage pulsing phase. In at least one embodiment, reducing voltage level from a high voltage level to a lower voltage level reduces peak ion energy at mask 804. In at least one embodiment, ions are slowed down sufficiently to reduce an ion bombardment rate. In at least one embodiment, duration of higher ion energy bombardment versus lower ion energy bombardment depends on a duty cycle of level-to-level pulsed voltage waveform. In at least one embodiment, duty cycle can determine extent to which mask 804 is provided respite against differential ion energy bombardment. In at least one embodiment, reducing voltage level from a high voltage level to a lower voltage level enables increase in preservation of mask 804.

In at least one embodiment, peak voltage is approximately 360V, and ratio between high voltage level and low voltage level is 3:1. In at least one embodiment, an ion angular spread corresponding to a higher voltage level is less than 70 percent of an ion angular spread corresponding to a lower voltage level.

FIG. 11D is a cross-sectional illustration 1130 of mask 804 following process to etch and form trench 1032 in FIG. 10D, in accordance with at least one embodiment. In at least one embodiment, plasma etch process utilized to form trench 1032 corresponds to a voltage bias condition on chuck electrode described in association with FIG. 9D.

Referring again to FIG. 11D, dashed line 1101 represents a reference line of a top of mask 804 prior to etching trench 1032. In at least one embodiment, mask 804 is eroded by an amount E₄. As shown, E₄ is approximately 0.87 E₁.

In at least one embodiment, reduced erosion of mask 804 is a result of a level-to-level pulsed voltage waveform, where mask 804 is provided respite against ion bombardment during a lower voltage phase. In at least one embodiment, peak voltage may be approximately 630V. In at least one embodiment, this voltage level is higher than peak voltage implemented which etching trench 1022 (FIG. 10A). In at least one embodiment, ratio between high voltage level and low voltage level is maintained at 3:1. In at least one embodiment, etch rate to form trench 1032 is substantially different from etch utilized to form trench 1022 (FIG. 10C). In at least one embodiment, mask erosion rate is substantially similar to a mask erosion rate observed in FIG. 11C, e.g., E₄˜E₃.

Referring again to FIG. 11D, in an embodiment, an ion angular spread corresponding to a higher voltage level is less than 70 percent of an ion angular spread corresponding to a lower voltage level.

Reduction in mask erosion can be advantageous, when plasma etch utilized to form trench 1032 (FIG. 10D) is further extended to produce trench 1032 having a depth that is greater than a depth of trench 1032, in accordance with at least one embodiment.

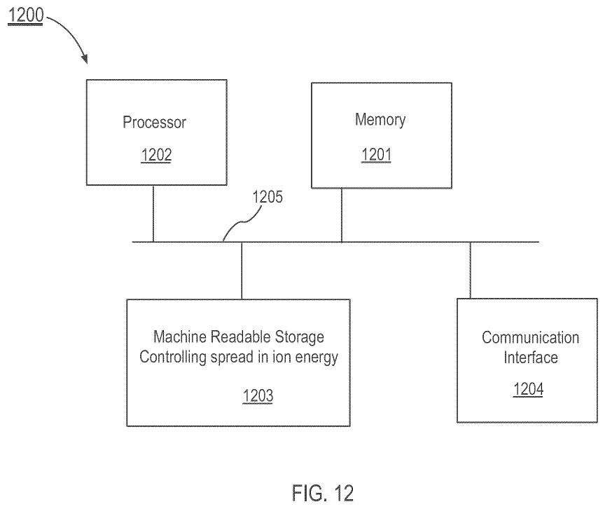

FIG. 12 illustrates processor system 1200 with machine-readable storage medium having instructions that when executed cause processor to enhance ion energy and reduce ion energy distribution in an inductively coupled plasma, in accordance with at least one embodiment. In at least one embodiment, processes may be stored in a machine-readable storage medium (e.g., 1203) as computer-executable instructions. In at least one embodiment, processor system 1200 comprises memory 1201, processor 1202, machine-readable storage medium 1203 (also referred to as tangible machine readable medium), communication interface 1204 (e.g., wireless or wired interface), and network bus 1205 coupled together as shown.

In at least one embodiment, processor 1202 is a Digital Signal Processor (DSP), an Application Specific Integrated Circuit (ASIC), a general-purpose Central Processing Unit (CPU), or a low power logic implementing a simple finite state machine to perform various processes described herein.

In at least one embodiment, various logic blocks of processor system 1200 are coupled together via network bus 1205. In at least one embodiment, any suitable protocol may be used to implement network bus 1205. In at least one embodiment, machine-readable storage medium 1203 includes instructions (also referred to as program software code/instructions) for enhancing ion energy and reducing ion angular spread in an inductively coupled plasma as described above.

In at least one embodiment, machine readable storage medium 1203 is a machine-readable storage medium with instructions for enhancing ion energy and reducing ion angular spread in an inductively coupled plasma. In at least one embodiment, machine readable storage medium 1203 has machine-readable instructions, that when executed, cause processor 1202 to perform method of measuring and/or reporting as discussed with reference to various embodiments.

In at least one embodiment, program software code/instructions associated with various embodiments may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In at least one embodiment, program software code/instructions associated with processes of various embodiments are executed by processor system 1200.

In at least one embodiment, program software code/instructions associated with various embodiments are stored in a computer executable machine-readable storage medium 1203 and executed by processor 1202. Here, computer executable machine-readable storage medium 1203 is a tangible machine-readable medium that can be used to store program software code/instructions and data that, when executed by a computing device, causes one or more processors (e.g., processor 1202) to perform a process. In at least one embodiment, process may comprise controlling a pulsed voltage waveform. In at least one embodiment, process may comprise controlling the pulsed voltage waveform to produce low and high voltage pulses with a predetermine duty cycle. In at least one embodiment, process may comprise modulating a spread in ion energy within a sheath region of a plasma by pulsed voltage waveform. In at least one embodiment, sheath region is adjacent to a substrate that is placed on an electrostatic chuck during processing. In at least one embodiment, pulsed voltage waveform is a combination two pulse voltage signals, where a first voltage pulse has a higher base voltage magnitude level and where a second voltage pulse has a lower base magnitude voltage level. In at least one embodiment, first voltage pulse comprises a first periodic voltage and second voltage pulse comprises a second periodic voltage. In at least one embodiment, first voltage pulse may be applied for a first time duration that is greater than, equal to or less than a second time duration of second voltage pulse. In at least one embodiment, first voltage pulse is an example of a first NCSWV signal, and second voltage pulse is an example of a second NCSWV signal, that is consistent with NCSWV signals 302 and 304 described in association with FIGS. 3-5.

Referring again to FIG. 12, in at least one embodiment, tangible machine-readable storage medium 1203 may include storage of executable software program code/instructions and data in various tangible locations, including for example ROM, volatile RAM, non-volatile memory and/or cache and/or other tangible memory. In at least one embodiment, portions of this program software code/instructions and/or data may be stored in any one of these storage and memory devices. In at least one embodiment, program software code/instructions can be obtained from other storage, including, e.g., through centralized servers or peer to peer networks and the like, including Internet. In at least one embodiment, different portions of software program code/instructions and data can be obtained at different times and in different communication sessions or in same communication session.

In at least one embodiment, software program code/instructions can be obtained in their entirety prior to execution of a respective software program or application. In at least one embodiment, portions of software program code/instructions and data can be obtained dynamically, e.g., just in time, when needed for execution. In at least one embodiment, some combination of these ways of obtaining software program code/instructions and data may occur, e.g., for different applications, components, programs, objects, modules, routines or other sequences of instructions or organization of sequences of instructions, by way of example. In at least one embodiment, it may not be required that data and instructions be on a tangible machine-readable medium in entirety at a particular instance of time.

In at least one embodiment, tangible machine-readable storage medium 1203 include but are not limited to recordable and non-recordable type media such as volatile and non-volatile memory devices, read only memory (ROM), random access memory (RAM), flash memory devices, floppy and other removable disks, magnetic storage medium, optical storage medium (e.g., Compact Disk Read-Only Memory (CD ROMS), Digital Versatile Disks (DVDs), etc.), among others. In at least one embodiment, software program code/instructions may be temporarily stored in digital tangible communication links while implementing electrical, optical, acoustical, or other forms of propagating signals, such as carrier waves, infrared signals, digital signals, etc. through such tangible communication links.

Example 1: A method of generating a voltage pulse, comprising: generating a first non-sinusoidal continuous wave voltage (NSCWV) signal for a first time duration of a clock cycle, the first NSCWV signal comprising a first base voltage and a first frequency; performing a first transition, the first transition comprising changing from the first NSCWV signal to a second NSCWV signal that is generated for a second time duration of the clock cycle, the second NSCWV signal comprising a second base voltage and a second frequency

Example 2: The method of example 1 further comprising performing a second transition, the second transition comprising changing from the second NSCWV signal back to the first NSCWV signal.

Example 3: The method of example 2 further comprising repeating the first transition and the second transition over the clock cycle.

Example 4: The method of example 1, wherein a magnitude of the first base voltage is greater than a magnitude of the second base voltage.

Example 5: The method of example 1, wherein an inverse of a sum of the first time duration and the second time duration defines a duty cycle of the voltage pulse, wherein the duty cycle of the first NSCWV signal is between 50-75%.

Example 6: The method of example 1, wherein a sum of the first time duration and the second time duration defines a pulse frequency of the voltage pulse, wherein the pulse frequency is between 1 Hz and 100 kHz.

Example 7: The method of example 1, wherein generating the first NSCWV signal further comprises: performing a first operation comprising increasing a first magnitude of voltage level from a reference voltage to the first base voltage over a first time interval; performing a second operation comprising ramping the voltage level from the first base voltage to a first peak voltage over a second time interval; performing a third operation comprising decreasing the voltage level from the first peak voltage to the reference voltage over a third time interval; performing a fourth operation comprising maintaining the voltage level at the reference voltage for a fourth time interval; and repeating the first operation, the second operation, the third operation and the fourth operation over the first time duration.

Example 8: The method of example 7, wherein the first frequency is equal to 1 divided by a sum of the first time interval, the second time interval, the third time interval and the fourth time interval.

Example 9: The method of example 8, wherein the first frequency is between 2 Hz and 400 kHz.

Example 10: The method of example 7, wherein the second time interval is greater than the first time interval or the third time interval by a factor of at least 100 and wherein the fourth time interval is greater than the first time interval or the third time interval by a factor of at least 100.

Example 11: The method of example 10, wherein a ratio between the second time interval to the fourth time interval is greater than or equal to 2:1.

Example 12: The method of example 10, wherein a ratio between the second time interval to the fourth time interval is 3:1.

Example 13: wherein the reference voltage is a first reference voltage, the voltage level is a first voltage level and wherein generating the second NSCWV signal further comprises: performing a fifth operation comprising increasing a second voltage level from a second reference voltage to the second base voltage over a fifth time interval; performing a sixth operation comprising ramping the second voltage level from the second base voltage to a second peak voltage over a sixth time interval; performing a seventh operation comprising decreasing the second voltage level from the second peak voltage to the second reference voltage over a seventh time interval; performing an eighth operation comprising maintaining the second voltage level at the second reference voltage for an eighth time interval; and repeating the fifth operation, the sixth operation, the seventh operation and the eighth operation over the second time duration.

Example 14: The method of example 13, wherein the second frequency is equal to 1 divided by a sum of the fifth time interval, the sixth time interval, the seventh time interval and the eighth time interval.

Example 15: The method of example 14, wherein the second frequency is between 2 Hz and 400 kHz.

Example 16: The method of example 13, wherein the sixth time interval is greater than the fifth time interval or the seventh time interval by a factor of at least 100 and wherein the eighth time interval is greater than the fifth time interval or the seventh time interval by a factor of at least 100.

Example 17: The method of example 16, wherein a ratio between the sixth time interval to the eighth time interval is greater than or equal to 2:1.

Example 18: The method of example 16, wherein a ratio between the sixth time interval to the eighth time interval is 3:1.

Example 19: The method of example 13, wherein a first magnitude of a first difference between the first base voltage and the first reference voltage is greater than a second magnitude of a second difference between second base voltage and the second base voltage and the second reference voltage.

Example 20: The method of example 13, wherein a third magnitude of the first peak voltage is greater than or less than a fourth magnitude of the second peak voltage.

Example 21: A method for operating a plasma chamber to increase ion energy and decrease ion angular spread at a surface of a substrate during an etch operation, the method comprising: placing the substrate on an electrostatic chuck within the plasma chamber, wherein the electrostatic chuck is electrically coupled to a non-sinusoidal continuous wave voltage (NSCWV) generator; forming a plasma in the plasma chamber, wherein the plasma produces a sheath comprising a sheath voltage; changing the sheath voltage by using a continuous wave voltage source to apply a voltage pulse at the electrostatic chuck, wherein applying the voltage pulse comprises: generating a first non-sinusoidal continuous wave voltage (NSCWV) signal for a first time duration of a clock cycle, the first NSCWV signal comprising a first base voltage and a first frequency; performing a first transition, the first transition comprising changing the first NSCWV signal to a second NSCWV signal that is generated for a second time duration of the clock cycle, the second NSCWV signal comprising a second base voltage and a second frequency.

Example 22: The method of example 21 further comprises performing a second transition, the second transition comprising changing the second NSCWV signal back to the first NSCWV signal.

Example 23: The method of example 22 further comprises repeating the first transition and the second transition over the clock cycle, wherein applying the voltage pulse effectuates a change in a spread in ion energy on the surface of the substrate.

Example 24: The method of example 21, wherein the first NSCWV signal comprises a first plurality of harmonics and wherein applying the second NSCWV comprises a second plurality of harmonics.

Example 25: The method of example 24, wherein the first plurality of harmonics and the second plurality of harmonics includes a 400 kHz fundamental harmonic and up and including to 10th harmonic.

Example 26: The method of example 21, wherein the voltage pulse further comprises: a positive period, a negative period, and a duty cycle between 0-100.

Example 27: The method of example 21, wherein applying the first NSCWV signal further comprises: a first negative voltage and a ramp to a second negative voltage, and wherein the second negative voltage is between 25-50% percent greater the first negative voltage.

Example 28: A method for operating a plasma chamber to change ion energy and ion angular spread at a surface of a substrate during an etch operation, the method comprising: placing the substrate on an electrostatic chuck within the plasma chamber, wherein the electrostatic chuck is electrically coupled to a non-sinusoidal voltage waveform generator; forming a plasma in the plasma chamber, wherein the plasma produces a sheath with a first sheath voltage; changing the first sheath voltage to a second sheath voltage by applying a first non-sinusoidal voltage waveform comprising a first periodic function at the electrostatic chuck to create a first voltage response on the electrostatic chuck that effectuates a first change in a spread in ion energy at the substrate; and changing the second sheath voltage to a third sheath voltage by applying a second non-sinusoidal voltage waveform comprising a second periodic function at the electrostatic chuck to create a second voltage response on the electrostatic chuck that effectuates a second change in a spread in ion energy at the substrate.

Example 29: The method of example 28, wherein the first non-sinusoidal voltage waveform comprises a first base voltage value and wherein the first non-sinusoidal voltage waveform produces a first ion angular spread at the substrate.

Example 30: The method of example 29, wherein the second non-sinusoidal voltage waveform comprises a second base voltage value, and wherein the second non-sinusoidal voltage waveform results in a second ion angular spread at the substrate.

Example 31: The method of example 30, wherein the first ion angular spread is less than 70 percent of the second ion angular spread.

Example 32: The method of example 28, wherein the first ion angular spread creates an etch rate that is 2 times an etch rate produced by the second non-sinusoidal voltage waveform.

Example 33: A machine-readable storage medium having machine executable instructions, that when executed, cause one or more machines to perform a method comprising: controlling a pulsed voltage waveform; controlling a periodic voltage; and controlling a spread in ion energy within a sheath region of a plasma by controlling the pulsed voltage waveform to produce low voltage pulse and high voltage pulse with a predetermined duty cycle.

Example 34: The machine-readable storage medium of example 33, wherein the pulsed voltage waveform has a duty cycle of at least 50% of the high voltage pulse.

Besides what is described herein, various modifications may be made to at least one embodiment thereof without departing from its scope. Therefore, illustrations of at least one embodiment herein should be construed as examples, and not restrictive to scope of at least one embodiment.

1. A method of generating a voltage pulse, comprising:
generating a first non-sinusoidal continuous wave voltage (NSCWV) signal for a first time duration of a clock cycle, the first NSCWV signal comprising a first base voltage and a first frequency; and
performing a first transition, the first transition comprising changing from the first NSCWV signal to a second NSCWV signal that is generated for a second time duration of the clock cycle, the second NSCWV signal comprising a second base voltage and a second frequency.

2. The method of claim 1 further comprising performing a second transition, the second transition comprising changing from the second NSCWV signal back to the first NSCWV signal.

3. The method of claim 2 further comprising repeating the first transition and the second transition over the clock cycle.

4. The method of claim 1, wherein a magnitude of the first base voltage is greater than a magnitude of the second base voltage.

5. The method of claim 1, wherein an inverse of a sum of the first time duration and the second time duration defines a duty cycle of the voltage pulse, and wherein the duty cycle of the first NSCWV signal is between 50-75%.

6. The method of claim 1, wherein a sum of the first time duration and the second time duration defines a pulse frequency of the voltage pulse, and wherein the pulse frequency is between 1 Hz and 100 kHz.

7. The method of claim 1, wherein generating the first NSCWV signal further comprises:
performing a first operation comprising increasing a first magnitude of voltage level from a reference voltage to the first base voltage over a first time interval;
performing a second operation comprising ramping the voltage level from the first base voltage to a first peak voltage over a second time interval;
performing a third operation comprising decreasing the voltage level from the first peak voltage to the reference voltage over a third time interval;
performing a fourth operation comprising maintaining the voltage level at the reference voltage for a fourth time interval; and
repeating the first operation, the second operation, the third operation and the fourth operation over the first time duration.

8. The method of claim 7, wherein the first frequency is equal to 1 divided by a sum of the first time interval, the second time interval, the third time interval and the fourth time interval.

9. The method of claim 8, wherein the first frequency is between 2 Hz and 400 kHz.

10. The method of claim 7, wherein the second time interval is greater than the first time interval or the third time interval by a factor of at least 100, and wherein the fourth time interval is greater than the first time interval or the third time interval by a factor of at least 100.

11. The method of claim 10, wherein a ratio between the second time interval to the fourth time interval is greater than or equal to 2:1.

12. The method of claim 10, wherein a ratio between the second time interval to the fourth time interval is 3:1.

13. The method of claim 7, wherein the reference voltage is a first reference voltage, the voltage level is a first voltage level and wherein generating the second NSCWV signal further comprises:
performing a fifth operation comprising increasing a second voltage level from a second reference voltage to the second base voltage over a fifth time interval;
performing a sixth operation comprising ramping the second voltage level from the second base voltage to a second peak voltage over a sixth time interval;
performing a seventh operation comprising decreasing the second voltage level from the second peak voltage to the second reference voltage over a seventh time interval;
performing an eighth operation comprising maintaining the second voltage level at the second reference voltage for an eighth time interval; and
repeating the fifth operation, the sixth operation, the seventh operation and the eighth operation over the second time duration.

14. The method of claim 13, wherein the second frequency is equal to 1 divided by a sum of the fifth time interval, the sixth time interval, the seventh time interval and the eighth time interval.

15. The method of claim 14, wherein the second frequency is between 2 Hz and 400 kHz.

16. The method of claim 13, wherein the sixth time interval is greater than the fifth time interval or the seventh time interval by a factor of at least 100, and wherein the eighth time interval is greater than the fifth time interval or the seventh time interval by a factor of at least 100.

17. The method of claim 16, wherein a ratio between the sixth time interval to the eighth time interval is greater than or equal to 2:1.

18. The method of claim 16, wherein a ratio between the sixth time interval to the eighth time interval is 3:1.

19. The method of claim 13, wherein a first magnitude of a first difference between the first base voltage and the first reference voltage is greater than a second magnitude of a second difference between the second base voltage and the second reference voltage.

20. The method of claim 13, wherein a third magnitude of the first peak voltage is greater than or less than a fourth magnitude of the second peak voltage.

21. A method for operating a plasma chamber to increase ion energy and decrease ion angular spread at a surface of a substrate during an etch operation, the method comprising:
placing the substrate on an electrostatic chuck within the plasma chamber, wherein the electrostatic chuck is electrically coupled to a non-sinusoidal continuous wave voltage (NSCWV) generator;
forming a plasma in the plasma chamber, wherein the plasma produces a sheath comprising a sheath voltage; and
changing the sheath voltage by using a continuous wave voltage source to apply a voltage pulse at the electrostatic chuck, wherein applying the voltage pulse comprises:
generating a first non-sinusoidal continuous wave voltage (NSCWV) signal for a first time duration of a clock cycle, the first NSCWV signal comprising a first base voltage and a first frequency; and
performing a first transition, the first transition comprising changing the first NSCWV signal to a second NSCWV signal that is generated for a second time duration of the clock cycle, the second NSCWV signal comprising a second base voltage and a second frequency.

22. The method of claim 21 further comprises performing a second transition, the second transition comprising changing the second NSCWV signal back to the first NSCWV signal.

23. The method of claim 22 further comprises repeating the first transition and the second transition over the clock cycle, wherein applying the voltage pulse effectuates a change in a spread in ion energy on the surface of the substrate.

24. The method of claim 21, wherein the first NSCWV signal comprises a first plurality of harmonics, and wherein applying the second NSCWV signal comprises a second plurality of harmonics.

25. The method of claim 24, wherein the first plurality of harmonics and the second plurality of harmonics includes a 400 kHz fundamental harmonic and up and including to 10^{th} harmonic.

26. The method of claim 21, wherein the voltage pulse further comprises: a positive period, a negative period, and a duty cycle between 0-100.

27. The method of claim 21, wherein applying the first NSCWV signal further comprises a first negative voltage and a ramp to a second negative voltage, and wherein the second negative voltage is between 25-50% percent greater the first negative voltage.

28. A method for operating a plasma chamber to change ion energy and ion angular spread at a surface of a substrate during an etch operation, the method comprising:
placing the substrate on an electrostatic chuck within the plasma chamber, wherein the electrostatic chuck is electrically coupled to a non-sinusoidal voltage waveform generator;
forming a plasma in the plasma chamber, wherein the plasma produces a sheath with a first sheath voltage;
changing the first sheath voltage to a second sheath voltage by applying a first non-sinusoidal voltage waveform comprising a first periodic function at the electrostatic chuck to create a first voltage response on the electrostatic chuck that effectuates a first change in a spread in ion energy at the substrate; and
changing the second sheath voltage to a third sheath voltage by applying a second non-sinusoidal voltage waveform comprising a second periodic function at the electrostatic chuck to create a second voltage response on the electrostatic chuck that effectuates a second change in a spread in ion energy at the substrate.

29. The method of claim 28, wherein the first non-sinusoidal voltage waveform comprises a first base voltage value, and wherein the first non-sinusoidal voltage waveform produces a first ion angular spread at the substrate.

30. The method of claim 29, wherein the second non-sinusoidal voltage waveform comprises a second base voltage value, and wherein the second non-sinusoidal voltage waveform results in a second ion angular spread at the substrate.

31. The method of claim 30, wherein the first ion angular spread is less than 70 percent of the second ion angular spread.

32. The method of claim 29, wherein the first ion angular spread creates an etch rate that is 2 times an etch rate produced by the second non-sinusoidal voltage waveform.

33. A machine-readable storage medium having machine executable instructions, that when executed, cause one or more machines to perform a method comprising:
controlling a pulsed voltage waveform;
controlling a periodic voltage; and
controlling a spread in ion energy within a sheath region of a plasma by controlling the pulsed voltage waveform to produce low voltage pulse and high voltage pulse with a predetermined duty cycle.

34. The machine-readable storage medium of claim 33, wherein the pulsed voltage waveform has a duty cycle of at least 50% of the high voltage pulse.
